(19) United States
(12) Patent Application Publication
(10) Pub. No.: US 2026/0271537 A1
(43) Pub. Date: Sep. 10, 2026

(54) DISPLAY PANEL AND ELECTRONIC APPARATUS

(71) Applicant: Samsung Display Co., Ltd., Yongin-si (KR)

(72) Inventors: Hyunsup Lee, Yongin-si (KR); Rangkyun Mok, Yongin-si (KR); Youngmin Park, Yongin-si (KR); Daeyoung Lee, Yongin-si (KR)

(21) Appl. No.: 19/436,877

(22) Filed: Dec. 30, 2025

(30) Foreign Application Priority Data
Jan. 10, 2025 (KR) 10-2025-0004374

(51) Int. Cl. H10K 59/122; H10K 59/35

(52) U.S. Cl. CPC H10K 59/122; H10K 59/353

(57) ABSTRACT

A display panel may include first and second pixel electrodes spaced from each other, a bank layer including openings respectively corresponding to the first and second pixel electrodes, an opposite electrode on the bank layer and overlapping the first and second pixel electrodes, a first intermediate layer between the first pixel electrode and the opposite electrode and including a first sub-stack and a second sub-stack, wherein each of the first and second sub-stacks includes a sub-emission layer configured to emit light of a first color, and a second intermediate layer between the second pixel electrode and the opposite electrode, and including a second emission layer configured to emit light of a second color, wherein a portion of the second intermediate layer is interposed between the first sub-stack and the second sub-stack, on a first portion of the bank layer between the first and second pixel electrodes.

### CROSS-REFERENCE TO RELATED APPLICATION

The present application claims priority to and the benefit of Korean Patent Application No. 10-2025-0004374, filed on Jan. 10, 2025, in the Korean Intellectual Property Office, the entire disclosure of which is incorporated herein by reference.

### BACKGROUND

### 1. Field

One or more embodiments of the present disclosure relate to a display panel and an electronic apparatus including the same.

### 2. Description of the Related Art

Display panels are widely utilized in various types (kinds) of electronic apparatuses. As the applications of display panels continue to expand across different industries, there is increasing demand for high-resolution display panels and for display panels having various shapes suitable for specific uses. Consequently, research and development efforts have been actively directed toward improving space utilization and achieving higher resolution in display panel technologies.

### SUMMARY

One or more aspects of embodiments of the present disclosure are directed toward a display panel that has a long life and implements high-quality images, and an electronic apparatus including the display panel. However, aspects of the present disclosure are not limited thereto. For example, the display panel may offer an extended operational lifespan and may be capable of rendering high-quality images.

Additional aspects will be set forth in part in the description which follows and, in part, will be apparent from the description, or may be learned by practice of the presented embodiments of the disclosure.

According to one or more embodiments, a display panel includes a first pixel electrode and a second pixel electrode spaced and/or apart (e.g., spaced apart or separated) from each other, a bank layer including a first opening and a second opening, wherein the first opening corresponds to the first pixel electrode, and the second opening corresponds to the second pixel electrode, an opposite electrode on the bank layer and overlapping the first pixel electrode and the second pixel electrode, a first intermediate layer interposed between the first pixel electrode and the opposite electrode, wherein the first intermediate layer includes a first sub-stack overlapping the first pixel electrode and including a first sub-emission layer configured to emit light of a first color, and a second sub-stack on the first sub-stack and including a second sub-emission layer configured to emit light of a same color as the first sub-emission layer, and a second intermediate layer interposed between the second pixel electrode and the opposite electrode, overlapping the second pixel electrode, and including a second emission layer configured to emit light of a second color different from the first color, wherein a portion of the second intermediate layer is interposed between the first sub-stack and the second sub-stack, on a first portion of the bank layer between the first pixel electrode and the second pixel electrode.

The display panel may further include a hole injection layer, wherein the hole injection layer may overlap the first pixel electrode, the first portion of the bank layer, and the second pixel electrode and be interposed between the first pixel electrode and the first intermediate layer and between the second pixel electrode and the second intermediate layer.

The first intermediate layer may include a charge generation layer interposed between the first sub-emission layer and the second sub-emission layer and including an electron generation layer and a hole generation layer, and the electron generation layer may be a sub-layer of the first sub-stack, and the hole generation layer may be a sub-layer of the second sub-stack.

The first sub-stack may include a first sub-emission layer, a first sub-hole transfer layer between the first pixel electrode and the first sub-emission layer, the electron generation layer on an opposite side of the first sub-hole transfer layer with the first sub-emission layer between the first sub-hole transfer layer and the electron generation layer, and a first sub-electron transfer layer between the first sub-emission layer and the electron generation layer.

The second sub-stack may include a second sub-emission layer, the hole generation layer between the first sub-stack and the second sub-emission layer, and a second sub-hole transfer layer between the hole generation layer and the second sub-emission layer.

A width of each of the electron generation layer and the first sub-electron transfer layer of the first sub-stack may be smaller than a width of the second sub-hole transfer layer.

The display panel may further include an electron transfer layer interposed between the opposite electrode and the second sub-stack of the first intermediate layer.

The electron transfer layer may extend to be interposed between the opposite electrode and the second intermediate layer and overlap the second sub-stack of the first intermediate layer, the second intermediate layer, and the first portion of the bank layer.

The first color may be blue, and the second color may be red or green.

The display panel may further include a third pixel electrode spaced and/or apart (e.g., spaced apart or separated) from the first pixel electrode, and a third intermediate layer interposed between the third pixel electrode and the opposite electrode, overlapping the third pixel electrode, and including a third emission layer configured to emit light of a third color different from the first color and the second color, wherein a portion of the third intermediate layer may be interposed between the first sub-stack and the second sub-stack, on a second portion of the bank layer between the first pixel electrode and the third pixel electrode.

According to one or more embodiments, an electronic apparatus includes a display panel including a first pixel, a second pixel, and a third pixel, wherein the display panel includes a first pixel electrode corresponding to the first pixel, a second pixel electrode corresponding to the second pixel and spaced and/or apart (e.g., spaced apart or separated) from the first pixel electrode, a bank layer including a first opening and a second opening, wherein the first opening corresponds to the first pixel electrode, and the second opening corresponds to the second pixel electrode, an opposite electrode on the bank layer and overlapping the first pixel electrode and the second pixel electrode, a first intermediate layer interposed between the first pixel electrode and the opposite electrode, wherein the first intermediate layer includes a first sub-stack overlapping the first pixel electrode and including a first sub-emission layer configured to emit light of a first color, and a second sub-stack on the first sub-stack and including a second sub-emission layer configured to emit light of a same color as the first sub-emission layer, and a second intermediate layer interposed between the second pixel electrode and the opposite electrode, overlapping the second pixel electrode, and including a second emission layer configured to emit light of a second color different from the first color, and wherein the first sub-stack includes an electron generation layer, and the second sub-stack includes a hole generation layer, and a portion of the second intermediate layer is interposed between the electron generation layer and the hole generation layer, on a first portion of the bank layer between the first pixel electrode and the second pixel electrode.

The display panel may further include a hole injection layer, wherein the hole injection layer may overlap the first pixel electrode, the first portion of the bank layer, and the second pixel electrode and be interposed between the first pixel electrode and the first intermediate layer and between the second pixel electrode and the second intermediate layer.

The first sub-stack may include a first sub-emission layer, a first sub-hole transfer layer between the first pixel electrode and the first sub-emission layer, the electron generation layer positioned on an opposite side of the first sub-hole transfer layer with the first sub-emission layer between the first sub-hole transfer layer and the electron generation layer, and a first sub-electron transfer layer between the first sub-emission layer and the electron generation layer.

The second sub-stack may include a second sub-emission layer, the hole generation layer between the first sub-stack and the second sub-emission layer, and a second sub-hole transfer layer between the hole generation layer and the second sub-emission layer.

A width of each of the electron generation layer and the first sub-electron transfer layer of the first sub-stack may be smaller than a width of the second sub-hole transfer layer.

The display panel may further include an electron transfer layer interposed between the opposite electrode and the second sub-stack of the first intermediate layer.

The electron transfer layer may extend to be interposed between the opposite electrode and the second intermediate layer and overlap the second sub-stack of the first intermediate layer, the second intermediate layer, and the first portion of the bank layer.

The first color may be blue, and the second color may be red or green.

The display panel may further include a third pixel electrode corresponding to the third pixel and spaced and/or apart (e.g., spaced apart or separated) from the first pixel electrode, and a third intermediate layer interposed between the third pixel electrode and the opposite electrode, overlapping the third pixel electrode, and including a third emission layer configured to emit light of a third color different from the first color and the second color, and a portion of the third intermediate layer may be interposed between the first sub-stack and the second sub-stack, on a second portion of the bank layer between the first pixel electrode and the third pixel electrode.

### BRIEF DESCRIPTION OF DRAWINGS

The accompanying drawings are included to provide a further understanding of the present disclosure and are incorporated in and constitute a part of the present disclosure. The drawings illustrate embodiments of the present disclosure and, together with the description, serve to explain principles of the present disclosure. The above and other aspects, features, and advantages of certain embodiments of the disclosure will be more apparent from the following description taken in conjunction with the accompanying drawings, in which:

FIG. 1A is a block diagram of an electronic apparatus according to one or more embodiments of the present disclosure;

FIG. 1B illustrates schematic diagrams of electronic apparatuses according to various embodiments of the present disclosure;

FIG. 2 is a schematic plan view of a display panel according to one or more embodiments of the present disclosure;

FIG. 3 is a schematic cross-sectional view of a display panel according to one or more embodiments of the present disclosure;

FIG. 4 is an enlarged cross-sectional view of a region corresponding to a first pixel and a second pixel of a display panel, according to one or more embodiments of the present disclosure, and is an enlarged cross-sectional view of a region IV of FIG. 3;

FIG. 5 is an enlarged cross-sectional view of a region corresponding to a first pixel and a third pixel of a display panel, according to one or more embodiments of the present disclosure, and is an enlarged cross-sectional view of a region V of FIG. 3;

FIG. 6 is a schematic diagram of a stacked structure of each pixel of a display panel, according to one or more embodiments of the present disclosure; and

FIG. 7 is an enlarged cross-sectional view of a region corresponding to a first pixel of a display panel, according to one or more embodiments of the present disclosure, and may correspond to a region VII of FIG. 3.

### DETAILED DESCRIPTION

Reference will now be made in more detail to one or more embodiments, examples of which are illustrated in the accompanying drawings, wherein like reference numerals refer to like elements throughout the disclosure, and duplicative descriptions thereof may not be provided for conciseness. In this regard, the presented embodiments may have different forms and should not be construed as being limited to the descriptions set forth herein. Accordingly, embodiments of the present disclosure are merely described in more detail, by referring to the drawings, to explain aspects of the present disclosure. As used herein, the term “and/or” or “or” may include any and all combinations of one or more of the associated listed items. Throughout the disclosure, the expression s such as “at least one of,” “one of,” and “selected from,” when preceding a list of elements, modify the entire list of elements and do not modify the individual elements of the list. For example, “at least one of a, b, or c” or expression “at least one selected from among a, b, and c” or expression “at least one selected from among a to c” indicates only a, only b, only c, both (e.g., simultaneously) a and b, both (e.g., simultaneously) a and c, both (e.g., simultaneously) b and c, all of a, b, and c, or variations thereof.

As one or more suitable modifications may be applied and numerous embodiments may be implemented, one or more example embodiments will be illustrated in the drawings and described in more detail in the written description. Effects and features, and methods for achieving them will be clarified with reference to one or more embodiments described herein in more detail with reference to the drawings. However, the embodiments may have different forms and should not be construed as being limited to the descriptions set forth herein.

Hereinafter, example embodiments will now be described in more detail with reference to the accompanying drawings. When described with reference to the drawings, identical or corresponding elements will be given the same reference numerals, and redundant description of these elements may not be provided.

It will be understood that although terms “first” and “second” may be used herein to describe one or more suitable elements, these elements should not be limited by these terms and these terms are only used to distinguish one element from another. Thus, a first element described could also be termed as a second or third element without departing from the spirit and scope of the disclosure.

In the following embodiments, the singular forms include the plural forms unless the context clearly indicates otherwise. For example, the singular forms “a,” “an,” “one,” and “the” are intended to include the plural forms as well, unless the context clearly indicates otherwise.

It will be understood that terms “comprise(s)/comprising,” “include(s)/including,” and “has(have)/having” as used herein specify the presence of stated features or elements, but do not preclude the presence or addition of one or more other features or elements. Additionally, the terms “comprise(s)/comprising,” “include(s)/including,” “have/has/having,” and/or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. Further, the use of “may” when describing embodiments of the present disclosure refers to “one or more embodiments of the present disclosure.

It will be further understood that, if (e.g., when) a layer, region, or element is referred to as being “on” another layer, region, or element, it may be directly or indirectly on the other layer, region, or element. For example, for example, one or more intervening layers, regions, or elements may be present therebetween. In contrast, if (e.g., when) an element is referred to as being “directly on” another element, there are no intervening element present therebetween.

Sizes of elements in the drawings may be exaggerated or reduced for convenience of description. For example, because sizes and thicknesses of elements in the drawings may be illustrated for convenience of explanation, embodiments of the present disclosure are not limited thereto.

If (e.g., when) a certain embodiment may be implemented differently, a specific process order may also be performed differently from the described order. For example, two processes that are successively described may be performed substantially concurrently (e.g., simultaneously) or performed in an order opposite to the order described.

It will be understood that if (e.g., when) a layer, region, or element is referred to as being connected to another layer, region, or element, it may be directly or indirectly connected to the other layer, region, or element. For example, one or more intervening layers, regions, or elements may be present therebetween. For example, as used herein, if (e.g., when) a layer, region, or element is referred to as being electrically connected to another element, it may be directly electrically connected to the other layer, region, or element or indirectly electrically connected to the other layer, region, or element via one or more intervening layers, regions, or elements.

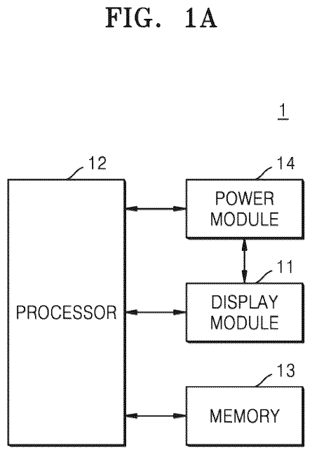

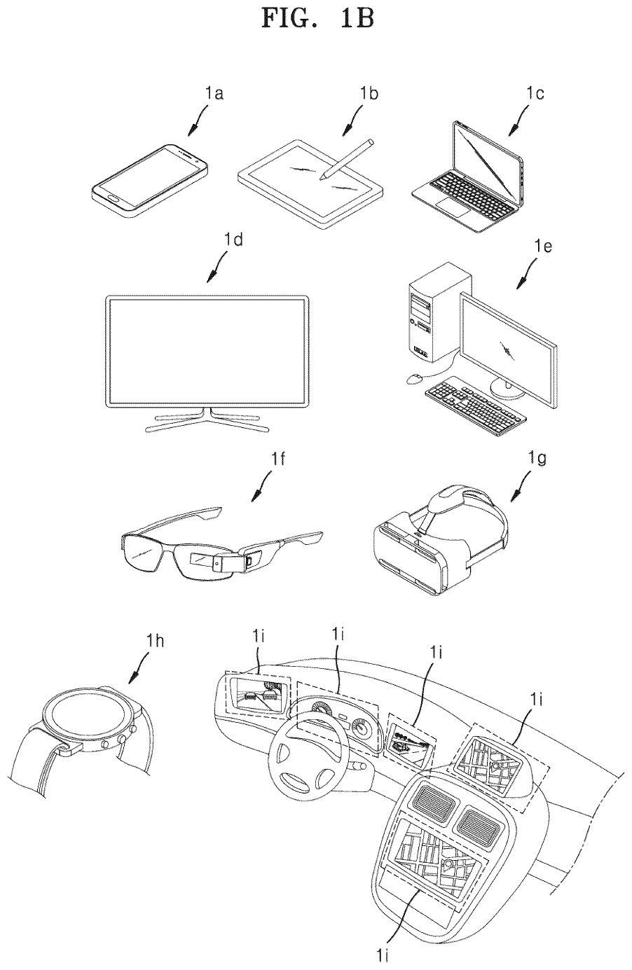

FIG. 1A is a block diagram of an electronic apparatus 1 according to one or more embodiments of the present disclosure. FIG. 1B illustrates schematic diagrams of electronic apparatuses according to one or more embodiments of the present disclosure.

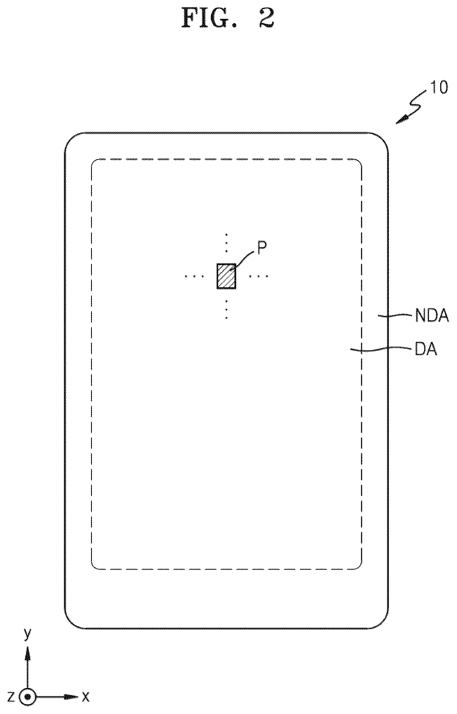

Referring to FIG. 1A, the electronic apparatus 1 according to one or more embodiments may include a display module 11, a processor 12, a memory 13, and a power module 14. The display module 11 may include a display panel 10 (see FIG. 2) according to one or more embodiments. In one or more embodiments, the display module 11 may include the display panel 10 (see FIG. 2), a gate driver, and a data driver. In one or more embodiments, the display panel 10 (see FIG. 2), the gate driver, and/or the data driver may be formed together in a process of forming the display panel 10 (see FIG. 2). In one or more embodiments, the gate driver and/or the data driver may be positioned over the display panel 10 (see FIG. 2) and electrically connected to the display panel 10 (see FIG. 2) through a bonding structure.

The processor 12 may include at least one of a central processing unit (CPU), an application processor (AP), a graphics processing unit (GPU), a communication processor (CP), or an image signal processor (ISP).

The memory 13 may store data information desired or required for the operation of the processor 12 and/or the display module 11. When the processor 12 executes an application stored in the memory 13, an image data signal and/or an input control signal may be transmitted to the display module 11, and the display module 11 may output image information through a display screen by processing the received signal.

The power module 14 may include a power supply module, such as a power adapter or a battery apparatus, and a power conversion module configured to generate power desired or required for the operation of the electronic apparatus 1 by converting power supplied by the power supply module.

At least one of the components of the electronic apparatus 1 described above may be included in a display apparatus including the display module 11. For example, in one or more embodiments, some of individual modules functionally included in a single module may be included in the display apparatus, and others thereof may be provided separately from the display apparatus. For example, the display apparatus may include the display module 11, and the processor 12, the memory 13, and the power module 14 may be provided in the form of other apparatuses within the electronic apparatus 1 other than the display apparatus.

Referring to FIG. 1B, the electronic apparatus including the display panel 10 (see FIG. 2) according to one or more embodiments may include an image display electronic apparatus, such as a smartphone 1a, a tablet personal computer (PC) 1b, a laptop computer 1c, a television (TV) 1d, or a desktop monitor 1e, a wearable electronic apparatus including a display module, such as smart glasses 1f, a head-mount display 1g, or a smartwatch 1h, and/or a vehicle electronic apparatus 1i including a display module, such as a central information display (CID) on an instrument panel, a center fascia, or a dashboard of a vehicle, or a room mirror display.

FIG. 2 is a schematic plan view of the display panel 10 according to one or more embodiments of the present disclosure.

Referring to FIG. 2, the display panel 10 may include a display area DA and a non-display area NDA positioned outside (e.g., adjacent) the display area DA. The display area DA may display an image through pixels P positioned in the display area DA. Each of the pixels P may include a display element, such as a light-emitting element/light emitting diode. Each of the pixels P may be to emit, for example, red, green, blue, or white light (e.g., combined white light).

The non-display area NDA is a non-display area that is positioned outside (e.g., adjacent) the display area DA and does not display an image, and, in one or more embodiments, may entirely surround the display area DA. A driver and/or the like configured to provide an electrical signal or power to the display area DA may be positioned in the non-display area NDA. A pad, which is an area to which an electronic element or a printed circuit board may be electrically connected, may be positioned in the non-display area NDA.

In one or more embodiments, as shown in FIG. 2, the display area DA may have a polygonal shape (e.g., a quadrangular shape) in which a length in a first direction (e.g., an x-direction) is shorter than a length in a second direction (e.g., a y-direction), but embodiments of the present disclosure are not limited thereto, for example, in one or more embodiments, the display area DA may have a polygonal shape (e.g., a quadrangular shape) in which the length in the second direction (e.g., the y-direction) is shorter than the length in the first direction (e.g., the x-direction). FIG. 2 illustrates that the display area DA has a substantially quadrangular shape, but embodiments of the present disclosure are not limited thereto. In one or more embodiments, the display area DA may have a suitable shape, such as an N-polygonal shape (where N is a natural number of 3 or more), a circular shape, or an elliptical shape. As shown in FIG. 2, in one or more embodiments, the display area DA may have a polygonal shape having round corners, but embodiments of the present disclosure are not limited thereto, for example. in one or more embodiments, the display area DA may have a shape including vertices where straight lines meet each other.

In one or more embodiments, a light-emitting diode, which is a display element included in the display panel 10, may include an organic light-emitting diode including an organic emission layer. In one or more embodiments, the light-emitting diode may include an inorganic light-emitting diode including an inorganic emission layer. A size of the light-emitting diode may be in micro-scale or nano-scale. For example, in one or more embodiments, the light-emitting diode may include a micro-light-emitting diode. In one or more embodiments, the light-emitting diode may include a quantum dot light-emitting diode including a quantum dot emission layer.

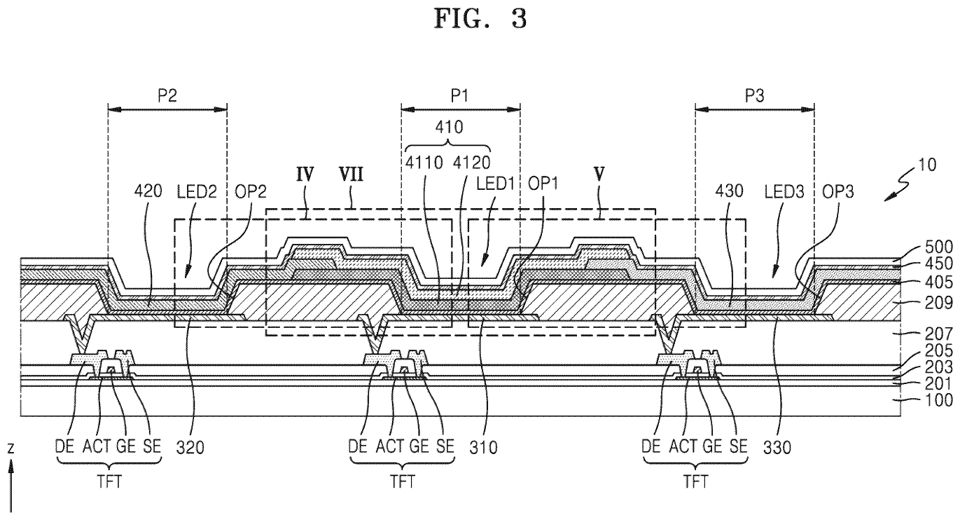

FIG. 3 is a schematic cross-sectional view of the display panel 10 according to one or more embodiments of the present disclosure. According to one or more embodiments, the display panel 10 may include light-emitting diodes over (e.g., on) a substrate 100, for example, may include first to third light-emitting diodes LED1, LED2, and LED3.

The substrate 100 may include glass, a metal, or a polymer resin. If (e.g., when) at least a portion of the display apparatus is bendable or the display apparatus is flexible, the substrate 100 may include a polymer resin. The substrate 100 may include a polymer resin such as polyethersulfone, polyacrylate, polyetherimide, polyethylene naphthalate, polyethylene terephthalate, polyphenylene sulfide, polyarylate, polyimide (PI), polycarbonate, or cellulose acetate propionate. In one or more embodiments, the substrate 100 may have a multilayer structure including at least two base layers each including a polymer resin, and an inorganic layer between the base layers.

A buffer layer 201 may be positioned on the substrate 100. The buffer layer 201 may include an inorganic material, such as silicon oxide, silicon nitride, and/or silicon oxynitride. The buffer layer 201 may increase the flatness of an upper surface of the substrate 100 and/or may prevent or minimize or reduce the penetration of impurities from the substrate 100 into a semiconductor layer ACT of a transistor TFT.

The transistor TFT may be positioned on the buffer layer 201. The transistor TFT may include the semiconductor layer ACT, a gate electrode GE, a source electrode SE, and a drain electrode DE.

The semiconductor layer ACT may be positioned on the buffer layer 201. In one or more embodiments, the semiconductor layer Act may include amorphous silicon or polysilicon. In one or more embodiments, the semiconductor layer ACT may include an oxide semiconductor material. The oxide semiconductor material of the semiconductor layer ACT may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), and zinc (Zn). In one or more embodiments, the semiconductor layer ACT may include an organic semiconductor material. The semiconductor layer ACT may include a channel region, a source region, and a drain region.

The gate electrode GE may include a metal, an alloy, a conductive metal oxide, or a transparent conductive material. For example, the gate electrode GE may include silver (Ag), an alloy containing Ag, molybdenum (Mo), an alloy containing Mo, aluminum (Al), an alloy containing Al, aluminum nitride (AlN), tungsten (W), tungsten nitride (WN), copper (Cu), nickel (Ni), Cr, chromium nitride (CrN), titanium (Ti), tantalum (Ta), platinum (Pt), scandium (Sc), indium tin oxide (ITO), or indium zinc oxide (IZO). The gate electrode GE may have a single-layer structure or a multilayer structure including one or more of the aforementioned materials.

The source electrode SE and the drain electrode DE may each include a metal, an alloy, a conductive metal oxide, or a transparent conductive material. For example, the source electrode SE and the drain electrode DE may each include Ag, an alloy containing Ag, Mo, an alloy containing Mo, Al, an alloy containing Al, AlN, W, WN, Cu, Ni, Cr, CrN, Ti, Ta, Pt, Sc, ITO, or IZO. The source electrode SE and the drain electrode DE may each have a single-layer structure or a multilayer structure including one or more of the aforementioned materials. For example, in one or more embodiments, the source electrode SE and the drain electrode DE may each have a two-layer structure including Ti/Al or a three-layer structure including Ti/Al/Ti.

A gate insulating layer 203 may be between the semiconductor layer ACT and the gate electrode GE. The gate insulating layer 203 may include an inorganic insulating material, such as silicon oxide, silicon nitride, and/or silicon oxynitride.

An interlayer insulating layer 205 may be positioned on the gate electrode GE. The source electrode SE and the drain electrode DE may both (e.g., simultaneously) be positioned on the interlayer insulating layer 205. The interlayer insulating layer 205 may include an inorganic insulating material, such as silicon oxide, silicon nitride, and/or silicon oxynitride.

FIG. 3 illustrates that the transistor TFT includes both (e.g., simultaneously) the source electrode SE electrically connected to a source region of the semiconductor layer ACT and the drain electrode DE electrically connected to a drain region of the semiconductor layer ACT, but embodiments of the present disclosure are not limited thereto. In one or more embodiments, a pixel circuit electrically connected to each of the first to third light-emitting diodes LED1, LED2, and LED3 may include a plurality of transistors, and a drain region of a first transistor, which is one of the plurality of transistors, may be electrically connected to a source region of a second transistor, which is another of the plurality of transistors. In this regard, the drain region of the first transistor and the source region of the second transistor may be integrally formed as a single body, the first transistor may not have a drain electrode DE, and the second transistor may not have a source electrode SE.

A planarization layer 207 may be positioned on the transistor(s) TFT. The planarization layer 207 may provide a flat upper surface. The planarization layer 207 may include an organic insulating material. In one or more embodiments, as shown in FIG. 3, the planarization layer 207 includes a single layer, but embodiments of the present disclosure are not limited thereto. In one or more embodiments, the planarization layer 207 may have a multilayer structure.

The first to third light-emitting diodes LED1, LED2, and LED3 may be positioned over (e.g., on) the planarization layer 207. The first light-emitting diode LED1 may include a first pixel electrode 310, an opposite electrode 500, and a first intermediate layer 410 between the first pixel electrode 310 and the opposite electrode 500. The second light-emitting diode LED2 may include a second pixel electrode 320, the opposite electrode 500, and a second intermediate layer 420 between the second pixel electrode 320 and the opposite electrode 500. The third light-emitting diode LED3 may include a third pixel electrode 330, the opposite electrode 500, and a third intermediate layer 430 between the third pixel electrode 330 and the opposite electrode 500.

The first pixel electrode 310, the second pixel electrode 320, and the third pixel electrode 330 may be arranged to be spaced and/or apart (e.g., spaced apart or separated) from one another. The opposite electrode 500 may be shared by the first to third light-emitting diodes LED1, LED2, and LED3. The opposite electrode 500 may be formed over the substrate 100 to overlap the first pixel electrode 310, the second pixel electrode 320, and the third pixel electrode 330.

In one or more embodiments, a first functional layer 405 and a second functional layer 450 may be shared by the first to third light-emitting diodes LED1, LED2, and LED3. The first functional layer 405 is a type (kind) of common layer and may be between the first to third pixel electrodes 310, 320, and 330 and the opposite electrode 500. For example, the first functional layer 405 may be between the first to third pixel electrodes 310, 320, and 330 and the first to third intermediate layer 410, 420, and 430. In one or more embodiments, the first functional layer 405 may include a hole injection layer (HIL). For example, in one or more embodiments, the first functional layer 405 may include a p-hole injection layer (p-HIL) including p-type (kind) impurities. The second functional layer 450 is a type (kind) of common layer and may be between the first to third intermediate layer 410, 420, and 430 and the opposite electrode 500. In one or more embodiments, the second functional layer 450 may include an electron transfer layer (or electron transport layer, ETL). In one or more embodiments, the second functional layer 450 may include an ETL and an electron injection layer (EIL).

In one or more embodiments, each of the first pixel electrode 310, the second pixel electrode 320, and the third pixel electrode 330 may include a (semi)-transmissive electrode and a reflective electrode. In one or more embodiments, each of the first pixel electrode 310, the second pixel electrode 320, and the third pixel electrode 330 may include a reflective layer and a transparent or semi-transparent electrode layer formed over the reflective layer, the reflective layer including Ag, magnesium (Mg), Al, Pt, palladium (Pd), gold (Au), Ni, neodymium (Nd), iridium (Ir), Cr, or any one or more compounds, alloys, or combinations thereof. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO). In one or more embodiments, each of the first pixel electrode 310, the second pixel electrode 320, and the third pixel electrode 330 may have a three-layer structure including ITO/Ag/ITO.

A bank layer 209 may cover an edge of each of the first pixel electrode 310, the second pixel electrode 320, and the third pixel electrode 330. The bank layer 209 may increase a distance between the edge of each of the first pixel electrode 310, the second pixel electrode 320, and the third pixel electrode 330 and the opposite electrode 500. Accordingly, the bank layer 209 may prevent or reduce arc generation at the edge of each of the first pixel electrode 310, the second pixel electrode 320, and the third pixel electrode 330.

The bank layer 209 may include an insulating material. In one or more embodiments, the bank layer 209 may include at least one organic insulating material selected from the group consisting of polyimide (PI), an acrylic resin, a benzocyclobutene-based resin, and a phenolic resin. In one or more embodiments, the bank layer 209 may include a colored material. The bank layer 209 may include a colored pigment, for example, a pigment of a certain color, such as white. In one or more embodiments, the bank layer 209 may be black. For example, in one or more embodiments, the bank layer 209 may include a PI binder and a pigment in which red, green, and blue are mixed. In one or more embodiments, the bank layer 209 may include a cardo binder resin and a mixture of a lactam black pigment and a blue pigment. In one or more embodiments, the bank layer 209 may include carbon black.

The bank layer 209 may include a first opening OP1, a second opening OP2, and a third opening OP3 overlapping the first pixel electrode 310, the second pixel electrode 320, and the third pixel electrode 330, respectively. The first opening OP1, the second opening OP2, and the third opening OP3 of the bank layer 209 may expose portions of the first pixel electrode 310, the second pixel electrode 320, and the third pixel electrode 330, respectively. The first opening OP1, the second opening OP2, and the third opening OP3 of the bank layer 209 may correspond to emission areas of the first to third light-emitting diodes LED1, LED2, and LED3, respectively, and the emission areas of the first to third light-emitting diodes LED1, LED2, and LED3 may correspond to emission areas of first to third pixels P1, P2, and P3 (or pixel areas of the first to third pixels P1, P2, and P3), respectively.

The first intermediate layer 410 may be between the first pixel electrode 310 and the opposite electrode 500 and overlap the first pixel electrode 310 and the opposite electrode 500. The first intermediate layer 410 may have a width (or size) greater than a width (or size) of the first opening OP1 of the bank layer 209, and an edge of the first intermediate layer 410 may be positioned over (e.g., on) an upper surface of the bank layer 209.

The first intermediate layer 410 may include a plurality of sub-layers, and the sub-layers may include a plurality of emission layers (hereinafter referred to as sub-emission layers) that emits light of a first color. In this regard, FIG. 3 illustrates that the first intermediate layer 410 includes a first sub-stack 4110 including a first sub-emission layer, and a second sub-stack 4120 including a second sub-emission layer.

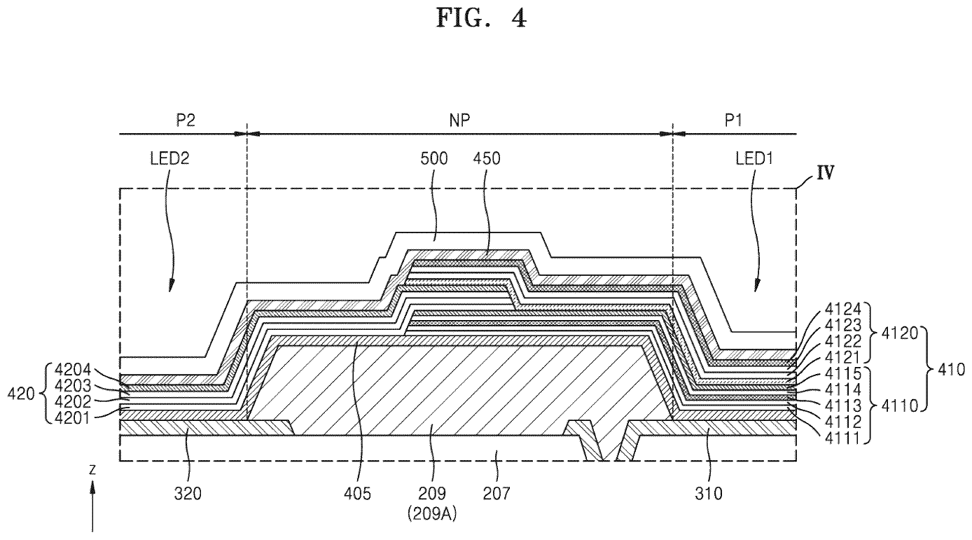

The first sub-stack 4110 may overlap the first pixel electrode 310 and extend onto the bank layer 209. An edge of the first sub-stack 4110 may be positioned over (e.g., on) an upper surface of the bank layer 209. One surface (e.g., a lower surface) of the first sub-stack 4110 opposite to (e.g., facing) the first pixel electrode 310 may be in direct contact with the first functional layer 405. For example, the one surface (e.g., the lower surface) of the first sub-stack 4110 opposite to (e.g., facing) the first pixel electrode 310 may entirely be in direct contact with the first functional layer 405. The first sub-stack 4110 may include a plurality of sub-layers including the first sub-emission layer, and the specific structure of the first sub-stack 4110 will be described in more detail with reference to FIG. 4.

The second sub-stack 4120 may overlap the first sub-stack 4110 on the first pixel electrode 310 and extend onto the bank layer 209. An edge of the second sub-stack 4120 may be positioned over the upper surface of the bank layer 209.

A portion of the second sub-stack 4120, for example, an inner region of the second sub-stack 4120, may be in direct contact with the first sub-stack 4110. The edge of the second sub-stack 4120 is spaced and/or apart (e.g., spaced apart or separated) from the edge of the first sub-stack 4110. An outer region of the second sub-stack 4120 including the edge of the second sub-stack 4120 is spaced and/or apart (e.g., spaced apart or separated) from an outer region of the first sub-stack 4110 including the edge of the first sub-stack 4110. For example, a portion of the second intermediate layer 420 (e.g., an outer region of the second intermediate layer 420) or a portion of the third intermediate layer 430 (e.g., an outer region of the third intermediate layer 430) may be interposed between the outer region of the second sub-stack 4120 and the outer region of the first sub-stack 4110. The outer region of the second sub-stack 4120 is not in direct contact with the outer region of the first sub-stack 4110 on the bank layer 209. The second sub-stack 4120 may include a plurality of sub-layers including the second sub-emission layer, and the specific structure of the second sub-stack 4120 will be described in more detail with reference to FIG. 4.

The second intermediate layer 420 may include a plurality of sub-layers. The second intermediate layer 420 may include an emission layer that emits light of a second color. A process of forming the second intermediate layer 420 may be performed between a process of forming the first sub-stack 4110 of the first intermediate layer 410 and a process of forming the second sub-stack 4120. Accordingly, a portion of the second intermediate layer 420 may be between the first sub-stack 4110 and the second sub-stack 4120 on the bank layer 209.

The third intermediate layer 430 may include a plurality of sub-layers. The third intermediate layer 430 may include an emission layer that emits light of a third color. A process of forming the third intermediate layer 430 may be performed between the process of forming the first sub-stack 4110 of the first intermediate layer 410 and the process of forming the second sub-stack 4120. Accordingly, a portion of the third intermediate layer 430 may be between the first sub-stack 4110 and the second sub-stack 4120 on the bank layer 209. A spatial configuration of the third intermediate layer 430 and the first intermediate layer 410 on the bank layer 209 may be similar to the spatial configuration of the second intermediate layer 420 and the first intermediate layer 410 on the bank layer 209 described above, and thus redundant description thereof is not repeated herein for conciseness. For example, the third intermediate layer 430 may be composed of multiple sub-layers, including an emission layer that emits light of a third color. It may be formed between the processes of forming the first sub-stack 4110 and the second sub-stack 4120 of the first intermediate layer 410. As a result, part of the third intermediate layer 430 is positioned between these two sub-stacks on the bank layer 209. The spatial arrangement of the third intermediate layer 430 relative to the first intermediate layer 410 is similar to that of the second intermediate layer 420.

The emission layers respectively included in the first to third intermediate layer 410, 420, and 430 may be to emit light of different colors. For example, the light of the first color, emitted from the first and second sub-emission layers respectively included in the first and second sub-stacks 4110 and 4120 of the first intermediate layer 410, may be blue light. The light of the second color, emitted from the emission layer included in the second intermediate layer 420, may be green (or red) light, and the light of the third color, emitted from the emission layer of the third intermediate layer 430, may be red (or green) light. The first intermediate layer 410 that emits blue light may have a type (kind) of tandem structure including the first and second sub-stacks 4110 and 4120, thereby improving light efficiency and life of the first light-emitting diode.

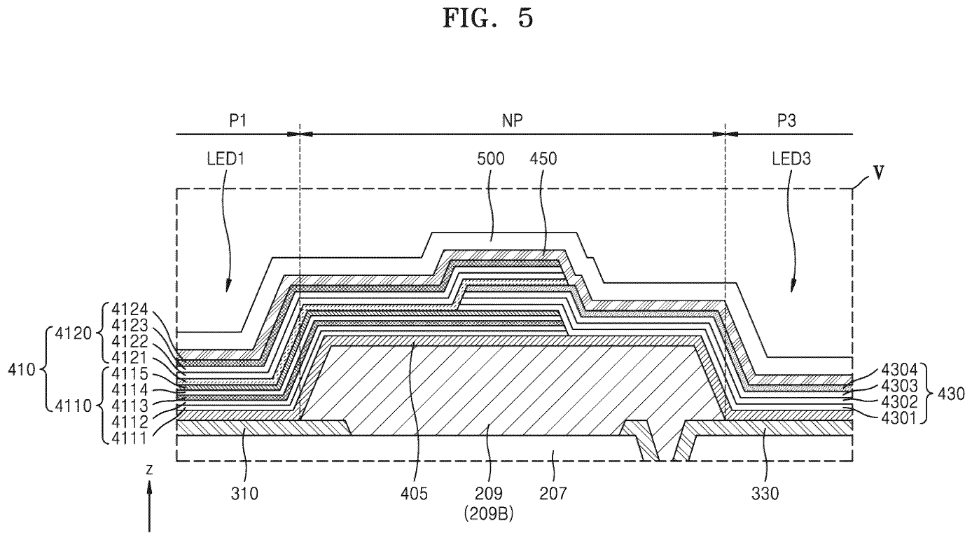

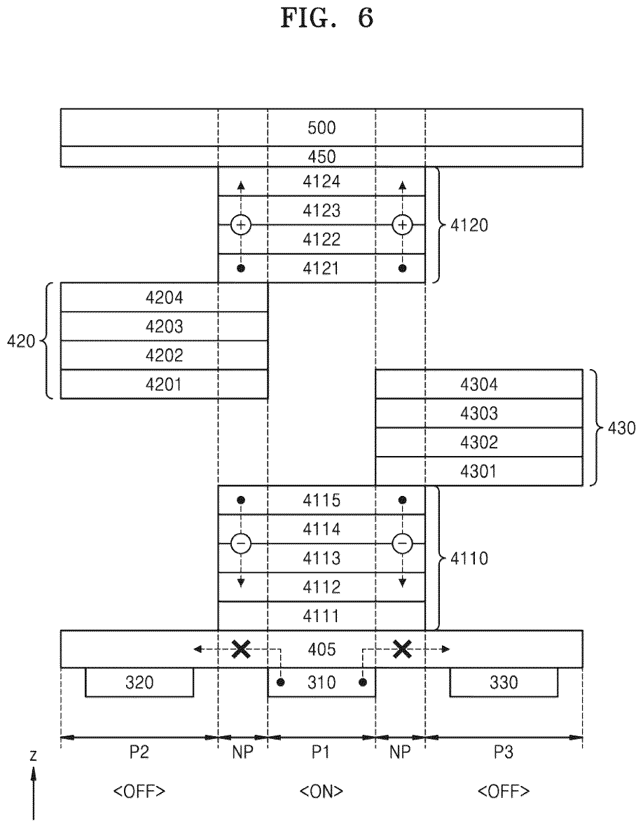

FIG. 4 is an enlarged cross-sectional view of a region corresponding to a first pixel P1 and a second pixel P2 of the display panel 10, according to one or more embodiments, and is an enlarged cross-sectional view of a region IV of FIG. 3. FIG. 5 is an enlarged cross-sectional view of a region corresponding to the first pixel P1 and a third pixel P3 of the display panel 10, according to one or more embodiments, and is an enlarged cross-sectional view of a region V of FIG. 3. FIG. 6 is a schematic diagram of a stacked structure of each pixel of the display panel 10, according to one or more embodiments.

Referring to FIG. 4, the bank layer 209 may be positioned on the first and second pixel electrodes 310 and 320, and the first functional layer 405 may be positioned on the bank layer 209. The first functional layer 405 may overlap the first pixel electrode 310, the second pixel electrode 320, and the bank layer 209 and may be interposed between the first pixel electrode 310 and the first intermediate layer 410 and between the second pixel electrode 320 and the second intermediate layer 420. The first functional layer 405 may include an HIL (e.g., a p-HIL) or may include an HIL (e.g., a p-HIL) and an HTL (hole transfer (transport) layer).

The first functional layer 405 may be in direct contact with the first pixel electrode 310 through the first opening OP1 and be in direct contact with the second pixel electrode 320 through the second opening OP2. The first functional layer 405 may be in direct contact with the upper surface of the bank layer 209. In this regard, FIG. 4 illustrates that the first functional layer 405 is in direct contact with a portion (hereinafter referred to as a first portion 209A) of the bank layer 209 between the first pixel electrode 310 and the second pixel electrode 320.

The first intermediate layer 410 may include a first sub-emission layer 4113 and a second sub-emission layer 4124. The first intermediate layer 410 may include a charge generation layer between the first sub-emission layer 4113 and the second sub-emission layer 4124. In this regard, FIG. 4 illustrates an electron generation layer 4115 as a negative charge generation layer between the first sub-emission layer 4113 and the second sub-emission layer 4124, and a hole generation layer 4121 as a positive charge generation layer.

The electron generation layer 4115 may include an n-type (kind) charge generation layer. The electron generation layer 4115 may supply electrons. The electron generation layer 4115 may include an n-type (kind) dopant material and an n-type (kind) host material. The n-type (kind) dopant material may be a metal from Group 1 or Group 2 of the periodic table, an organic material capable of injecting electrons, or a mixture thereof. For example, the n-type (kind) dopant material may include any one of an alkali metal or an alkaline earth metal. In one or more embodiments, the electron generation layer 4115 may include an organic layer doped with an alkali metal, such as lithium (Li), sodium (Na), potassium (K), or cesium (Cs), or an alkaline earth metal, such as Mg, strontium (Sr), barium (Ba), or radium (Ra), but embodiments of the present disclosure are not limited thereto. The n-type (kind) host material may include an organic material capable of transferring electrons. For example, the n-type (kind) host material may include one or more selected from among tris(8-hydroxyquinolinato)aluminum (Alq3), 8-hydroxyquinolinolato-lithium (Liq), 2-(4-biphenyl)-5-(4-tert-butylphenyl)-1,3,4 oxadiazole (PBD), 3-(4-biphenyl)4-phenyl-5-tert-butylphenyl-1,2,4-triazole (TAZ), spiro-PBD, bis(2-methyl-8-quinolinolato)-4-(phenylphenolato)aluminium (BAlq), SAlq, 2,2′,2-(1,3,5-benzinetriyl)-tris(1-phenyl-1-H-benzimidazole (TPBi), oxadiazole, triazole, phenanthroline, benzoxazole, and benzothiazole, but embodiments of the present disclosure are not limited thereto.

The hole generation layer 4121 may include a p-type (kind) charge generation layer. The hole generation layer 4121 may supply holes. The hole generation layer 4121 may include a p-type (kind) host material and a p-type (kind) dopant material. The p-type (kind) dopant material may include a metal oxide, an organic material such as tetrafluoro-tetracyanoquinodimethane (F4-TCNQ) or hexaazatriphenylene-hexacarbonitrile (HAT-CN), or a metal material such as vanadium pentoxide (V₂O₅), molybdenum oxide (MoOₓ), or tungsten trioxide (WO₃), but embodiments of the present disclosure are not limited thereto. The p-type (kind) host material may include an organic material capable of transferring holes, for example, a material including one or more of N,N-dinaphthyl-N,N′-diphenyl benzidine (N,N′-bis(naphthalen-1-yl)-N,N′-bis(phenyl)-2,2′-dimethylbenzidine) (NPD), N,N′-bis-(3-methylphenyl)-N,N′-bis-(phenyl)-benzidine (TPD), and 4,4′,4-Tris(N-3-methylphenyl-N-phenyl-amino)-triphenylamine (MTDATA), but embodiments of the present disclosure are not limited thereto.

The electron generation layer 4115 and the hole generation layer 4121 may be in direct contact with each other in an area corresponding to the first opening OP1, for example, an area corresponding to the first pixel P1. The electron generation layer 4115 and the hole generation layer 4121 may be at least partially spaced and/or apart (e.g., spaced apart or separated) from each other in a non-pixel area NP. The electron generation layer 4115 is a sub-layer of the first sub-stack 4110, the hole generation layer 4121 is a sub-layer of the second sub-stack 4120, and an outer region of the electron generation layer 4115 including an edge of the electron generation layer 4115 and an outer region of the hole generation layer 4121 including an edge of the hole generation layer 4121 may not be in direct contact with each other and may be spaced and/or apart (e.g., spaced apart or separated) from each other in a stacking direction (e.g., a z-direction) of the electron generation layer 4115 and the hole generation layer 4121.

The first sub-stack 4110 of the first intermediate layer 410 may include the first sub-emission layer 4113 that emits light of a first color (e.g., blue), a first sub-hole transfer layer (or hole transport layer, HTL) 4111, which is an HTL between the first pixel electrode 310 and the first sub-emission layer 4113, the electron generation layer 4115 positioned on an opposite side of the first sub-HTL 4111 with the first sub-emission layer 4113 therebetween, and a first sub-ETL 4114 between the first sub-emission layer 4113 and the electron generation layer 4115.

In one or more embodiments, the first sub-stack 4110 may include a first auxiliary layer 4112 between the first sub-HTL 4111 and the first sub-emission layer 4113. The first auxiliary layer 4112 may improve the light generation efficiency of the first sub-emission layer 4113 by adjusting the hole charge balance. The first auxiliary layer 4112 may have a thickness determined or set according to a resonance period of light emitted from the first sub-emission layer 4113 and may improve the color impurity of light emitted from the first sub-emission layer 4113.

The second sub-stack 4120 of the first intermediate layer 410 may include the second sub-emission layer 4124 that emits light of the first color, the hole generation layer 4121 between the first sub-stack 4110 and the second sub-emission layer 4124, and a second sub-HTL 4122, which is an HTL between the hole generation layer 4121 and the second sub-emission layer 4124.

In one or more embodiments, the second sub-stack 4120 may include an auxiliary layer 4123 between the second sub-HTL 4122 and the second sub-emission layer 4124. The auxiliary layer 4123 may improve the light generation efficiency of the second sub-emission layer 4124 by adjusting the hole charge balance.

The second functional layer 450, for example, an ETL, may be between the second sub-stack 4120 and the opposite electrode 500 and may overlap the second sub-stack 4120. The second functional layer 450, for example, the ETL, is a common layer and may extend over the second intermediate layer 420 positioned in the second pixel P2 and overlap the second intermediate layer 420 and the first portion 209A of the bank layer 209 between the first pixel P1 and the second pixel P2.

The second intermediate layer 420 may include a second emission layer 4204 that emits light of a second color (e.g., green), a second HTL 4201 between the second pixel electrode 320 and the second emission layer 4204, and a resonance auxiliary layer 4202 between the second HTL 4201 and the second emission layer 4204. The resonance auxiliary layer 4202 is a layer for adjusting a resonance distance of the second color and may be a type (kind) of auxiliary HTL.

The second intermediate layer 420 may include a second auxiliary layer 4203 between the resonance auxiliary layer 4202 and the second emission layer 4204. The second auxiliary layer 4203 may improve the light generation efficiency of the second emission layer 4204 by adjusting the hole charge balance. The color purity of light emitted from the second emission layer 4204 may be improved.

Referring to FIG. 5 in addition to FIG. 3, the bank layer 209 may be positioned on the first to the third pixel electrodes 310, 320, and 330, and the first functional layer 405 may be positioned on the bank layer 209. The first functional layer 405 may overlap the first pixel electrode 310, the third pixel electrode 330, and the bank layer 209 and may be between the first pixel electrode 310 and the first intermediate layer 410 and between the third pixel electrode 330 and the third intermediate layer 430.

The first functional layer 405 may be in direct contact with the first pixel electrode 310 through the first opening OP1 and may be in direct contact with the third pixel electrode 330 through the third opening OP3. The first functional layer 405 may be in direct contact with the upper surface of the bank layer 209. In this regard, FIG. 5 illustrates that the first functional layer 405 is in direct contact with a portion (hereinafter referred to as a second portion 209B) of the bank layer 209 between the first pixel electrode 310 and the third pixel electrode 330. The specific structure of the first intermediate layer 410 shown in FIG. 5 is the same as described above with reference to FIG. 4.

The third intermediate layer 430 may include a third emission layer 4304 that emits light of a third color (e.g., red), a third HTL 4301 between the third pixel electrode 330 and the third emission layer 4304, and a resonance auxiliary layer 4302 between the third HTL 4301 and the third emission layer 4304. The resonance auxiliary layer 4302 is a layer for adjusting a resonance distance of the third color and may be a type (kind) of auxiliary HTL.

The third intermediate layer 430 may include a third auxiliary layer 4303 between the resonance auxiliary layer 4302 and the third emission layer 4304. The third auxiliary layer 4303 may improve the light generation efficiency of the third emission layer 4304 by adjusting the hole charge balance.

Referring to FIGS. 4, 5, and 6, in the non-pixel area NP, a portion of each of the second intermediate layer 420 and the third intermediate layer 430 may be between the first sub-stack 4110 and the second sub-stack 4120.

As shown in FIG. 4 and FIG. 6, on the first portion 209A of the bank layer 209 corresponding to the non-pixel area NP, a portion of the second intermediate layer 420 may be between the first sub-stack 4110 and the second sub-stack 4120. For example, a portion of each of the sub-layers (e.g., the second HTL 4201, the resonance auxiliary layer 4202, the second auxiliary layer 4203, and the second emission layer 4204) of the second intermediate layer 420 may be between the electron generation layer 4115 of the first sub-stack 4110 and the hole generation layer 4121 of the second sub-stack 4120.

As shown in FIGS. 5 and 6, on the second portion 209B of the bank layer 209 corresponding to the non-pixel area NP, a portion of the third intermediate layer 430 may be between the first sub-stack 4110 and the second sub-stack 4120. For example, a portion of each of the sub-layers (e.g., the third HTL 4301, the resonance auxiliary layer 4302, the third auxiliary layer 4303, and the third emission layer 4304) of the third intermediate layer 430 may be between the electron generation layer 4115 of the first sub-stack 4110 and the hole generation layer 4121 of the second sub-stack 4120.

In one or more embodiments, through a structure in which each of the second intermediate layer 420 and the third intermediate layer 430 is between the first sub-stack 4110 and the second sub-stack 4120, the emission of unintended light from a certain area of the display panel 10 may be prevented.

As a comparative example, a case where the second sub-stack 4120 is positioned below the second intermediate layer 420 and the third intermediate layer 430, the first light-emitting diode LED1 is turned on, and the second and third light-emitting diodes LED2 and LED3 are turned off is described. In this case, some of holes of the first pixel electrode 310 move toward the second and third pixels P2 and P3 through the first functional layer 405, and some of holes generated from the hole generation layer 4121 of the second sub-stack 4120 move to the second intermediate layer 420 and the third intermediate layer 430 through the second sub-stack 4120. Accordingly, unintended light may be emitted from an area corresponding to the second and third pixels P2 and P3 and/or the non-pixel area NP.

As another comparative example, a case where the first sub-stack 4110 is positioned over the second intermediate layer 420 and the third intermediate layer 430, the first light-emitting diode LED1 is turned on, and the second and third light-emitting diodes LED2 and LED3 are turned off is described. In this case, some electrons that did not form excitons in the first sub-emission layer 4113 of the first sub-stack 4110 may move in a-z direction and be introduced into the second intermediate layer 420 and the third intermediate layer 430, and some holes of the first pixel electrode 310 may move to the non-pixel area NP through the first functional layer 405. In this case, light corresponding to the second color or the third color may be unintentionally emitted from the non-pixel area NP. The aforementioned phenomenon may be prominent at low tones.

However, according to one or more embodiments of the present disclosure, through the structure described with reference to FIGS. 3 to 5, the emission of unintended light may be prevented as described above.

For example, as shown in FIG. 6, if (e.g., when) the first light-emitting diode LED1 is turned on and the second and third light-emitting diodes LED2 and LED3 are each turned off, electrons of the electron generation layer 4115 of the first sub-stack 4110 corresponding to the first light-emitting diode LED1 move in a-z direction, and holes of the hole generation layer 4121 of the second sub-stack 4120 move in a z-direction. Thus, even if (e.g., when) the first and second sub-stacks 4110 and 4120 overlap the second and third intermediate layers 420 and 430 in the non-pixel area NP, light corresponding to the second color and the third color may be prevented from being unintentionally emitted in the non-pixel area NP.

As shown in FIG. 6, if (e.g., when) the first light-emitting diode LED1 is turned on and the second and third light-emitting diodes LED2 and LED3 are each turned off, some of the holes of the first pixel electrode 310 may move toward the second and third pixels P2 and P3 through the non-pixel area NP via the first functional layer 405, but the movement of the holes may be blocked by the first sub-stack 4110 on the first functional layer 405 in the non-pixel area NP. For example, electrons that fail to form excitons in the first sub-emission layer 4113 of the first sub-stack 4110 may accumulate below the first sub-emission layer 4113 (e.g., in the-z direction), and holes that are directed toward the second and third pixels P2 and P3 through the first functional layer 405 may be trapped by the electrons. For example, the path of the holes toward the second and third pixels P2 and P3 through the first functional layer 405 may be blocked. Accordingly, if (e.g., when) the second and third light-emitting diodes LED2 and LED3 are turned off, the light of the second color and/or the light of the third color may be prevented from being dimly turned on in the second and third pixels P2 and P3.

For example, when only the first light-emitting diode LED1 is activated, the device structure and charge dynamics are configured to suppress unintended light emission from the second and third light-emitting diodes LED2 and LED3, particularly in non-pixel areas NP. The first sub-stack 4110 and associated charge blocking mechanisms prevent or protect from hole migration toward adjacent pixels through the first functional layer 405, while accumulated electrons in the emission layer further inhibit hole movement. This configuration helps maintain color purity and prevents unwanted illumination in inactive pixels, thereby enhancing display performance and image quality.

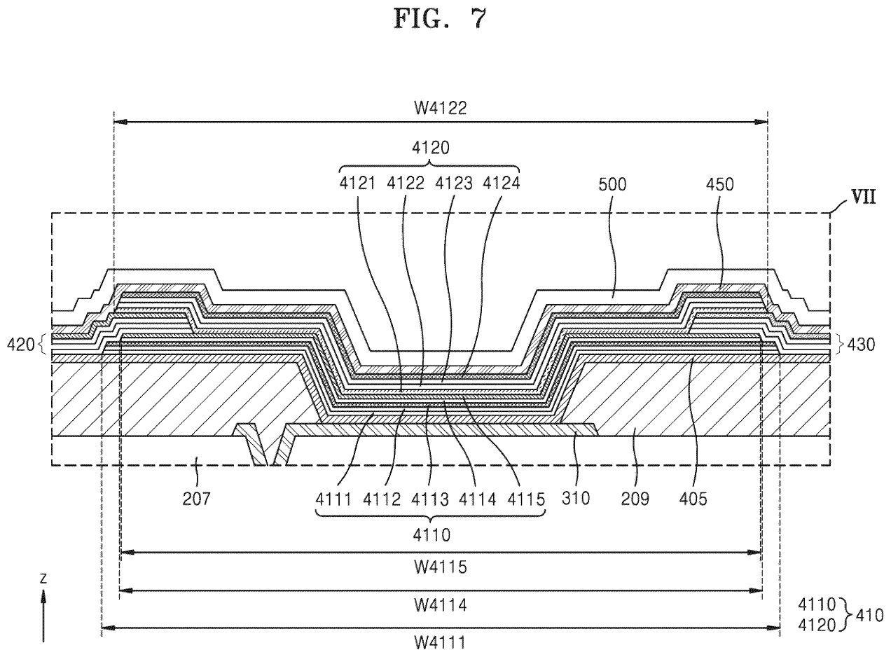

FIG. 7 is an enlarged cross-sectional view of a region corresponding to a first pixel of the display panel 10, according to an embodiment, and may correspond to a region VII of FIG. 3.

Referring to FIG. 7, the first intermediate layer 410 may include the first sub-stack 4110 and the second sub-stack 4120, and the second intermediate layer 420 or the third intermediate layer 430 may be between the first sub-stack 4110 and the second sub-stack 4120 in the non-pixel area NP. The specific configurations of the first intermediate layer 410, the second intermediate layer 420, and the third intermediate layer 430 are as described above with reference to FIGS. 4 to 6, and the differences are mainly described in more detail herein.

In one or more embodiments, a width W4115 or W4114 of each of the electron generation layer 4115 and/or the first sub-ETL 4114 of the first intermediate layer 410 may be smaller than the width of the HTL of the first intermediate layer 410. For example, the width W4115 of the electron generation layer 4115 and the width W4114 of the first sub-ETL 4114 may each be smaller than a width W4122 of the second sub-HTL 4122. A width W4111 of the first sub-HTL 4111 may be relatively larger than the width W4115 of the electron generation layer 4115 and the width W4114 of the first sub-ETL 4114.

As described above with reference to FIG. 6, if (e.g., when) the first pixel P1 is turned on and the second and third pixels P2 and P3 are each turned off, electrons that fail to form excitons in the second sub-emission layer 4124 among electrons moving from the opposite electrode 500 toward the first intermediate layer 410 may move toward the second sub-HTL 4122. As a comparative example, if (e.g., when) the width W4115 of the electron generation layer 4115 and the width W4114 of the first sub-ETL 4114 are larger than the width of the second sub-emission layer 4124, the second sub-HTL 4122 may be in contact with the electron generation layer 4115 and/or the first sub-ETL 4114 due to a process error. In this case, light emission from the first sub-stack 4110 may exceed the intended brightness range or affect surrounding layers, such as the second and third intermediate layers 420 and 430, but this may be prevented if (e.g., when) the aforementioned structure is used.

As described above, the instant disclosure has been described with reference to the one or more embodiments shown in the accompanying drawings, but should be considered in a descriptive sense only. Those of ordinary skill in the art will understand that one or more suitable modifications and changes to the embodiments may be made therefrom. Therefore, the true technical scope of protection of the disclosure should be defined by the technical spirit of the appended claims and equivalents thereof.

According to one or more embodiments, a display panel and an electronic apparatus having improved display quality and life through a relatively simple structure may be provided. The effects described above are merely examples, and the effects of the disclosure are not limited to those described above.

In the context of the present application and unless otherwise defined, the terms “use,” “using,” and “used” may be considered synonymous with the terms “utilize,” “utilizing,” and “utilized,” respectively.

Spatially relative terms, such as “beneath,” “below,” “lower,” “above,” “upper,” and/or the like, may be used herein for descriptive purposes, and, thereby, to describe one element or feature's relationship to another element(s) or feature(s) as shown in the drawings. Spatially relative terms are intended to encompass different orientations of a device in use, operation, and/or manufacture in addition to the orientation depicted in the drawings. For example, if (e.g., when) the device in the drawings is turned upside down, elements described as “below” or “beneath” other elements or features would then be oriented “above” or “on” the other elements or features. Thus, in one or more embodiments, the example term “below” may encompass both (e.g., simultaneously) an orientation of above and below directions. Furthermore, the device may be otherwise oriented (e.g., rotated 90 degrees or at other orientations), and, as such, the spatially relative descriptors used herein interpreted accordingly.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

The display panel, the display device, the electronic device/apparatus, the display panel/device-manufacturing apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

It should be understood that the embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display panel comprising:
a first pixel electrode and a second pixel electrode spaced from each other;
a bank layer comprising a first opening and a second opening, the first opening corresponding to the first pixel electrode, and the second opening corresponding to the second pixel electrode;
an opposite electrode on the bank layer and overlapping the first pixel electrode and the second pixel electrode;
a first intermediate layer interposed between the first pixel electrode and the opposite electrode, the first intermediate layer comprising
a first sub-stack overlapping the first pixel electrode and comprising a first sub-emission layer configured to emit light of a first color, and
a second sub-stack on the first sub-stack and comprising a second sub-emission layer configured to emit light of a same color as the first sub-emission layer; and
a second intermediate layer interposed between the second pixel electrode and the opposite electrode, overlapping the second pixel electrode, and comprising a second emission layer configured to emit light of a second color different from the first color,
wherein a portion of the second intermediate layer is interposed between the first sub-stack and the second sub-stack, on a first portion of the bank layer between the first pixel electrode and the second pixel electrode.

2. The display panel of claim 1, further comprising a hole injection layer,
wherein the hole injection layer
overlaps the first pixel electrode, the first portion of the bank layer, and the second pixel electrode and
is interposed between the first pixel electrode and the first intermediate layer and between the second pixel electrode and the second intermediate layer.

3. The display panel of claim 1, wherein
the first intermediate layer comprises a charge generation layer interposed between the first sub-emission layer and the second sub-emission layer and comprising an electron generation layer and a hole generation layer,
the electron generation layer is a sub-layer of the first sub-stack, and
the hole generation layer is a sub-layer of the second sub-stack.

4. The display panel of claim 3, wherein the first sub-stack comprises:
a first sub-emission layer;
a first sub-hole transfer layer between the first pixel electrode and the first sub-emission layer;
the electron generation layer on an opposite side of the first sub-hole transfer layer with the first sub-emission layer between the first sub-hole transfer layer and the electron generation layer; and
a first sub-electron transfer layer between the first sub-emission layer and the electron generation layer.

5. The display panel of claim 4, wherein the second sub-stack comprises:
a second sub-emission layer;
the hole generation layer between the first sub-stack and the second sub-emission layer; and
a second sub-hole transfer layer between the hole generation layer and the second sub-emission layer.

6. The display panel of claim 5, wherein a width of each of the electron generation layer and the first sub-electron transfer layer of the first sub-stack is smaller than a width of the second sub-hole transfer layer.

7. The display panel of claim 5, further comprising an electron transfer layer interposed between the opposite electrode and the second sub-stack of the first intermediate layer.

8. The display panel of claim 7, wherein the electron transfer layer
extends to be interposed between the opposite electrode and the second intermediate layer and
overlaps the second sub-stack of the first intermediate layer, the second intermediate layer, and the first portion of the bank layer.

9. The display panel of claim 1, wherein the first color is blue, and the second color is red or green.

10. The display panel of claim 1, further comprising:
a third pixel electrode spaced from the first pixel electrode; and
a third intermediate layer interposed between the third pixel electrode and the opposite electrode, overlapping the third pixel electrode, and comprising a third emission layer configured to emit light of a third color different from the first color and the second color,
wherein a portion of the third intermediate layer is interposed between the first sub-stack and the second sub-stack, on a second portion of the bank layer between the first pixel electrode and the third pixel electrode.

11. An electronic apparatus comprising a display panel comprising a first pixel, a second pixel, and a third pixel,
wherein the display panel comprises:
a first pixel electrode corresponding to the first pixel;
a second pixel electrode corresponding to the second pixel and spaced from the first pixel electrode;
a bank layer comprising a first opening and a second opening, the first opening corresponding to the first pixel electrode, and the second opening corresponding to the second pixel electrode;
an opposite electrode on the bank layer and overlapping the first pixel electrode and the second pixel electrode;
a first intermediate layer interposed between the first pixel electrode and the opposite electrode, the first intermediate layer comprising
a first sub-stack overlapping the first pixel electrode and comprising a first sub-emission layer configured to emit light of a first color, and
a second sub-stack on the first sub-stack and comprising a second sub-emission layer configured to emit light of a same color as the first sub-emission layer; and
a second intermediate layer interposed between the second pixel electrode and the opposite electrode, overlapping the second pixel electrode, and comprising a second emission layer configured to emit light of a second color different from the first color, and
wherein the first sub-stack comprises an electron generation layer, and the second sub-stack comprises a hole generation layer, and
a portion of the second intermediate layer is interposed between the electron generation layer and the hole generation layer, on a first portion of the bank layer between the first pixel electrode and the second pixel electrode.

12. The electronic apparatus of claim 11, wherein the display panel further comprises a hole injection layer, and
the hole injection layer
overlaps the first pixel electrode, the first portion of the bank layer, and the second pixel electrode and
is interposed between the first pixel electrode and the first intermediate layer and between the second pixel electrode and the second intermediate layer.

13. The electronic apparatus of claim 11, wherein the first sub-stack comprises:
a first sub-emission layer;
a first sub-hole transfer layer between the first pixel electrode and the first sub-emission layer;
the electron generation layer positioned on an opposite side of the first sub-hole transfer layer with the first sub-emission layer between the first sub-hole transfer layer and the electron generation layer; and
a first sub-electron transfer layer between the first sub-emission layer and the electron generation layer.

14. The electronic apparatus of claim 13, wherein the second sub-stack comprises:
a second sub-emission layer;
the hole generation layer between the first sub-stack and the second sub-emission layer; and
a second sub-hole transfer layer between the hole generation layer and the second sub-emission layer.

15. The electronic apparatus of claim 14, wherein a width of each of the electron generation layer and the first sub-electron transfer layer of the first sub-stack is smaller than a width of the second sub-hole transfer layer.

16. The electronic apparatus of claim 11, wherein the display panel further comprises an electron transfer layer interposed between the opposite electrode and the second sub-stack of the first intermediate layer.

17. The electronic apparatus of claim 16, wherein the electron transfer layer
extends to be interposed between the opposite electrode and the second intermediate layer and
overlaps the second sub-stack of the first intermediate layer, the second intermediate layer, and the first portion of the bank layer.

18. The electronic apparatus of claim 11, wherein the first color is blue, and the second color is red or green.

19. The electronic apparatus of claim 11, wherein the display panel further comprises:
a third pixel electrode corresponding to the third pixel and spaced from the first pixel electrode; and
a third intermediate layer interposed between the third pixel electrode and the opposite electrode, overlapping the third pixel electrode, and comprising a third emission layer configured to emit light of a third color different from the first color and the second color, and
a portion of the third intermediate layer is interposed between the first sub-stack and the second sub-stack, on a second portion of the bank layer between the first pixel electrode and the third pixel electrode.
